(19) United States
(12) Patent Application Publication
(10) Pub. No.: US 2004/0129447 A1
(43) Pub. Date: Jul. 8, 2004

(54) Electrical and electro-mechanical applications of superconducting phenomena in carbon nanotubes

(76) Inventors: Pieder Beeli, Cypress, CA (US); Guo-Meng Zhao, Hacienda Heights, CA (US)

Correspondence Address: ROBERT W. STROZIER, SUITE 930, 2925 BRIARPARK DRIVE, HOUSTON, TX, 77042, US

(21) Appl. No.: 10/636,317

(22) Filed: Aug. 7, 2003

Related U.S. Application Data
(60) Provisional application No. 60/401,516, filed on Aug. 7, 2002.

(51) Int. Cl. H01F 5/00; H01B 1/00; C04B 2/00; H01B 12/00; C01B 31/00; B07C 5/344

(52) U.S. Cl. 174/125.1; 335/299; 505/100; 423/445 R; 174/113 R; 209/571; 505/230

(57) ABSTRACT

Electrical or electro-mechanical apparatuses are disclosed that include a plurality of superconducting nanotubes or a plurality of superconducting nanotube bundles, especially superconducting carbon nanotubes and a stabilizing means or structure, where the nanotubes are maximally proximate and where the means stabilizes the nanotubes to increase mechanical durability. Methods of sorting nanotubes based on their conductive properties are also disclosed.

### RELATED APPLICATIONS

This application claims provisional priority to U.S. Provisional Patent Application Serial No. 60/401,516, filed 7 Aug. 2002.

### BACKGROUND OF THE INVENTION

1. Field of the Invention

The present invention relates to the general field of carbon nanotubes.

More particularly, the present invention relates to: energy storage, to coils and nested coils, comprising superconducting carbon nanotubes; to stabilizing an intimate proximity among tubes in bundles of superconducting carbon nanotubes by various means; to transmission lines comprising carbon nanotubes; to electrical and electromechanical devices comprising carbon nanotubes, nanotube coils, nested coils, bundles or mixtures or combinations thereof and to methods for making and using same and to methods for sorting carbon nanotubes, enriching a concentration of superconducting nanotubes and separating nanotubes based on their conductive properties. Many features of the materials including carbon nanotubes are a consequence of coherent (phase locked) superconductivity in carbon nanotubes that persist at temperatures even well above room temperature. This result enables the useful feature of near zero resistivity in applications—without the use of cryogens.

2. Description of the Related Art

With the discovery of superconductivity at temperatures above liquid nitrogen's boiling point in the 1980's, applications for superconductivity have been growing. The uses of superconductivity include high power applications, high magnetic field applications, energy storage and a very sensitive transducer (e.g. bolometer).

Superconducting magnetic energy storage (SMES) is the name given to the art of storing energy in the form of a magnetic field so that the energy can be quickly retrieved and converted into electrical energy. Stored as a circulating current or magnetic field, this energy can be held for a long period of time with only small losses by virtue of the low losses associated with superconductivity.

SMES systems are already commercially available. GE/American Superconductor is one supplier.

Superconductors also have a niche in cell phone repeater stations where superconducting thin film filters provide a sharper frequency cutoff than their non-superconducting versions. This feature along with a higher gain (less attenuation) means that the end user experiences less interference, less noise and that cell phone repeater stations with superconducting thin film technology can be more sparsely distributed over a given area to achieve the same coverage.

Although many superconducting materials are now recognized in the art, there is still a need in the art for more versatile superconductors which are easy to prepare and fabricate and that are capable of superconducting at or above room temperature and for a method to make, sort, and use such superconductors.

### DEFINITIONS

A nanotube is a small tube having a diameter between about 0.42 and about 1000 nanometers.

A carbon nanotube (CNT) is a nanotube comprising substantially elemental carbon.

A multiwalled carbon nanotube (MWNT) is a collection of nested CNTs which share a common axis.

A single walled carbon nanotube (SWNT) is a CNT comprising only one shell or layer.

A superconducting carbon nanotube (SCNT) is a CNT that superconducts [1-6].

Doping is the process by which the electronic carrier density is changed. Doping alters the overall electrical transport behavior. Like cuprate superconductors which can be doped into the superconducting state or non-superconducting state, SCNTs can be doped to be optimally doped superconductors, non-optimally doped superconductors or to be non-superconductors [3].

CNTs can either have a metallic or a semiconducting chirality. If (n-m) mod 3=0, the tube is said to have a metallic chirality [7]. Otherwise the tube's chirality is semiconducting. Technically, zigzag tubes (n,0) have a small gap making them semiconducting, even for (n) mod 3=0[8]. However this gap is small. Because the Fermi level can easily be doped outside this small gap, we ignore the semiconducting behavior in these (3n,0) zigzag tubes.

Both semiconducting and metallic chirality CNTs can be made to superconduct via the doping of carriers into the CNT.

Superconducting tubes are quasi-1D superconductors and can be Josephson coupled to exhibit less dissipation or resistivity.

A straight CNT is parallel to another straight CNT, if the two CNTs are aligned along the same direction. Such tubes will have a length l in common, where l is the minimum of the length of both tubes laid side-by-side. Over the distance l, one CNT will have analogous points that are separated from analogous points on the second CNT, by the same or nearly the same distance.

A CNT is proximate to another CNT, if the two CNTs are close to each other. Proximity increases as more points on one CNT become closer to nearest points on the other CNT. For two straight CNTs that share a length l, proximity is maximized when the CNTs are parallel. Further, if a difference in tube diameter s exceeds about 0.68 μm, the tubes will exhibit the greatest proximity if the tubes are nested over 1, i.e., the smaller diameter tube is inside the larger diameter tube. If the difference in tube diameters for two SWNTs is less than about 0.68 nm, it may not be possible to nest the tubes and proximity is then maximized if the tubes are parallel and in contact over the length l.

Maximal proximity means CNTs are arranged in parallel with an optimal or minimized distance d between analogous points on the parallel disposed CNTs, i.e., d represents a minimized distance between the CNTs when accounting for all analogous points on the parallel CNTs. Such superconducting tubes are said to be maximally proximate superconducting carbon nanotubes (MPSCNTs). In similar fashion, a plurality or collection of CNTs are maximally proximate when a configuration that minimizes the sum of all the distances between analogous points on all of the CNTs is assumed. Because nesting, when geometrically possible, is a more effective means of ensuring maximal proximity between CNTs, MWNTs are an ideal configuration for achieving maximal proximity. Thus, MWNTs, which can already be synthesized with an inherent tight nesting, represent both a practical and an ideal configuration for achieving maximal proximity. By bringing collections of CNTs into maximal proximity, then macro-conductive structures can be constructed where one CNT or CNT bundle begins near or before another CNT or CNT bundle ends. Thus percolation can arise from intertube coupling and create a macroscopic continuity even though the CNTs themselves are of a microscopic dimension.

If such proximate tubes are jointly shaped so that the tubes have the same or similar separation along every point, but are not aligned in a straight line, then these tubes are also said to be parallel.

A coherent superconducting carbon nanotube line (CSCNTL) is a collection of superconducting carbon nanotubes (SCNTs) which exhibits a greater “phase coherence” (compared to the separated tubes) and therefore a lower resistivity than exhibited by the separated tubes. MPSCNTs comprises a CSCNTL. For example, consider the collection of SCNTs comprises SCNTs of equal or nearly equal length where the ends of the tubes only are in electrical contact with each other. The net resistance of the collection is smaller if the SCNTs are closer to each other. Proximity enhances a superconducting synergy. The phase coherence is a result of Josephson coupling between individual SCNTs that causes the net resistance of two adjacent SCNTs to be less than the parallel combination of their separated resistances.

We now consider a parallel collection of SCNTs and consider variations in their net resistance as a function of the number and proximity of SCNTs that comprise the collection. The proximity induced synergy in SCNTs results in the formation of maximally proximate collections of SCNTs which have a lowered resistivity than their well-separated analogs. A dc resistivity of less than 1 μOhm-cm is readily obtainable with aligned collections of SCNTs. Thus, increasing the number of SCNTs that have maximal proximity in a collection of SCNTs results in more coherent superconducting transport within the construct [3]. The greater the number of SCNTs that have maximal proximity in the collection, the greater will be the number of conductive channels, and, therefore, the lower the contact resistance. Moreover, the more maximally proximate SCNTs in the collection, the lower will be the collective and individual on-tube resistances. The net resistance of our parallel collection of SCNTs decreases as both the contact and on-tube resistances decrease.

Individual SCNTs, especially individual single-walled carbon nanotubes (SWCNTs), can exhibit a large amount of phase slip resistivity. The resistivity of these individual SWCNTs can lower significantly when these SWCNTs are brought into maximal proximity with each other during the construction of SCNTLs or CSCNTLs.

The term orphan superconducting carbon nanotube (OSCNT) means any SCNT having a resistivity that lowers appreciably when brought into maximal proximity with another SCNT or superconductor. Thus, SCNTs are either CSCNTs or OSCNTs. The distinction between an CSCNT and OSCNT is rather qualitative, but the distinction is evidenced from a relative change in superconducting properties as the isolated SCNT in question is brought close to an isolated CSCNT. An OSCNT is therefore distinguished from a CSCNT because an OSCNT exhibits a larger relative change in its resistivity when it is brought near an CSCNT as compared to the relative change in resistivity when an CSCNT is brought near another CSCNT. For example, the resistivity of an OSCNT maybe reduced by as much as about 60%, while the resistivity of an CSCNT maybe reduced by only about 6%.

The construction of a CSCNTL can compete with the maximally proximate criteria. Because lengths of superconducting wire are sought that are longer than the length of the comprising SCNTs, SCNTs can be put “end to end” or in series, instead of in parallel. Putting SCNTs in series extends the length of the superconducting line, while putting SCNTs in parallel enhances the superconductivity of the superconducting line. Both series and parallel constructions serve valuable but competing objective. Therefore, one needs to strike a balance between these two competing effects for maximum benefit in a particular application. Achieving great superconducting phase coherence, but not having a wire of sufficient length may limit the scope of applications. Similarly, having a robust connection between two contacts with an OSCNT may not be advantageous over a connection involving a non-superconducting wire that is less lossy.

A superconductor has a complex penetration depth (\tilde{λ}). \tilde{λ} determines the wavelength of the electromagnetic wave inside a superconductor and the length scale over which the wave attenuates (δ_{A}) [9]. δ_{A} is called the amplitude of the attenuation length scale. It is the distance where the amplitude of a forward propagating plane wave drops to about 36.8% of its original value. \tilde{λ} is related to the (dc) London penetration depth (λ_{L}) [9]. Inside a bulk superconductor, a plane electromagnetic wave attenuates to about 36.8% of its original value at the surface of the bulk superconductor at a depth given by δ_{A}, where

$${d}_{A} = \frac{{\vert \tilde{λ} \vert}^{2}}{ℜ ( \tilde{λ} )}$$

and [symbol] is the real operator [9].

A composite SCNT transmission line is composed of numerous SCNTs such that the length of the transmission line far exceeds the length of the longest SCNT inside the transmission line.

An intrinsic SCNT transmission line has a length which is equal or nearly equal to the length of its constituent tubes.

### SUMMARY OF THE INVENTION

The present invention provides methods for stabilizing proximity, preferably maximal proximity, between two CNTs or between neighboring CNTs in CNT bundles, especially SCNTs in SCNT bundles. The methods for stabilizing proximity, preferably maximal proximity, include wrapping the bundle with another tube-like material, encasing the bundle in a matrix, braiding of the tubes in the bundle, braiding bundles, spiral winding of the tubes, spiral winding of the bundles, or mixtures or combinations thereof.

The present invention also provides energy storage and transmission apparatuses comprising SCNTs.

The present invention also provides an insulated SCNT wire comprising at least one MWNT.

The present invention also provides electrical and electromechanical apparatuses comprising at least one component including at least one SCNT.

The present invention also provides a method for sorting carbon nanotubes based on their superconductivity including the step of continuously measuring a property of an OSCNT, the reference tube, while decreasing a separation between the reference tube and the nanotube to be sorted, where the property can be any property relatable to superconductivity such as resistance, diamagnetic response, tunneling propensity, etc., or combinations thereof. If the nanotube to be tested sorted is a SCNT, then the property of the OSCNT undergoes a significant change as the to be-sorted tube is brought into proximity, preferably maximal proximity, to the reference tube; otherwise, the property undergoes a less significant change. Because doping and chirality can vary the T_{c} values of the to-be-sorted tube over a large range, changes in the measured property in the reference tube can conceivably change anywhere from 0 to 100% or more. If this measurement is done at high temperatures, then one can probe if the tested tube is a robust superconductor at high temperatures. If this measurement is repeated at lower temperatures, then tubes that were not so robustly superconducting may be found to robustly superconduct at that lower temperature. This method can be performed at various temperatures to ascertain a temperature dependence of the superconductivity. Preferably this method is performed in an environment of low magnetic fields so that the Josephson coupling can be most sensitively exploited. Measuring multiple superconducting properties—of both the OSCNT and the combination of the OSCNT and the to-be-sorted tube—is a means of improving the confidence level in this contactless sorting process.

The present invention also provides a method for enriching a concentration of superconducting nanotubes in a macroscopic collection of carbon nanotubes including the steps of suspending a macroscopic collection of nanotubes in an electrically non-conductive suspending agent having sufficient viscosity to suspend the nanotube, while allowing movement of the nanotube through the suspension under the influence of an externally applied field or a field gradient which induces a force on the nanotubes. The field gradient is preferably a magnetic field gradient. Preferably, magnetic moments of the SCNTs are aligned by applying an external field across the suspension. Alternatively, better alignment of the moments may be achieved via two applied external magnetic fields. One magnetic field is stationary or static field and the other field sweeps through a solid angle to help bring the remaining unaligned SCNTs into alignment with the static magnetic field. Once sufficient alignment is achieved, this second field, the sweeping field, may be deactivated. Once the magnetic moments of the nanotubes, especially SCNTs, have been sufficiently aligned, a field gradient can be applied across the suspension. The field gradient can either be parallel or antiparallel to the aligned magnetic moments for optimal displacement of the nanotubes. The gradient couples to the moments of each nanotube and causes the nanotubes to migrate through the suspension depending on the nanotube's magnetic moment. SCNTs, which have pronounced magnetic moments relative to non-SCNTs, selectively migrate to one end of the suspension. Preferably, the static field and the field gradient are maintained for a time sufficient for nanotube migration to occur. Preferably, a tube concentration in the suspension is selected to reduce tube entanglement which can impede the orientation of the nanotube moments and impede the migration of the nanotubes or tube bundles through the suspension in response to the field gradient. The method can also include the step of heating the collection of nanotubes to an elevated temperature and then cooling the suspension in a large field (to induce magnetic moments in the nanotubes without the need for an externally applied magnetic field). Because force between magnetic dipoles may cause clustering of SCNTs and such clustering may trap non-SCNTs or may cause misalignment of SCNTs, it may be preferred to heat the tubes to a high temperature and then cool them in a substantially zero field environment as opposed to field cooling. In this manner, the SCNTs will have a lower moment and less clustering may occur. Then, the static magnetic field strength can be adjusted so that the induced moments in the SCNTs are not too large reducing clustering, yet are large enough to couple with the magnetic field gradient to cause migration. It seems preferable then that the cooling from high temperatures is performed in a substantially zero field environment to reduce the clustering of SCNTs and misaligning of SCNTs. The application of a field gradient to a suspension of nanotubes creates a force on the nanotubes that depends on the magnitude of their magnetic moments. The greater the magnitude of the magnetic moments of a nanotube, the better it couples to the field gradient. Thus, the SCNTs will be concentrated in one portion of the suspension after the migration time has lapsed. The SCNT rich region of the suspension can then be harvested. The harvested regions can then be re-suspended and re-migrated to further refine the SCNTs depending on their magnetic moments. T he method can also be performed under active agitation or vibration to facilitate relative movement of the nanotubes through the suspension and to facilitate inter nanotubes movement in the suspension. CNTs. Preferred agitation includes sonication.

The present invention also provides a chromagraphic method for separating superconducting from nonsuperconducting nanotubes from an ensemble of nanotubes including preparing a suspension of an ensemble of nanotubes, where the individual nanotubes are unaligned and largely untangled so that the tubes can be separated without the application of too great an external force induced by an externally applied field or field gradient. Preferably, the suspending agent has a sufficient viscosity to suspend the nanotubes, while allowing movement of the nanotubes through the suspension when under influence of an externally applied static magnetic field and a field gradient across the suspension. The field generates and/or aligns moments associated with or induced in the nanotubes, while the field gradient applies a force to the tubes which have a magnetic moment and can be either parallel or antiparallel to the aligned magnetic moments. Thus, the method permits separation and selective enrichment of the collections of nanotubes into superconducting nanotubes and non-superconducting nanotubes. By maintaining the field and field gradient for a time sufficient for nanotube migration to occur to form a concentration gradient of the nanotubes depending on their magnetic moments. The method can also include the step of removing nanotubes based on their position in the suspension to obtain a collection of carbon nanotube materials having a desired range of magnetic susceptibility, i.e., the suspension will separation into SCNT rich and SCNT poor regions. By reversing the orientation of the field to the field gradient from parallel to anti-parallel (or vice-versa), the resulting concentration gradient of SCNT rich and poor regions will be reversed. Preferably, the separation results in the formation of a material having greater than 1 metallic chirality nanotube for every 2 semiconducting chirality nanotubes (the ratio that arises if one assumes that each chirality has equal probability of being realized) and material having greater than 2 semiconducting chirality nanotubes for every one metallic chirality nanotube. Regions higher in SCNTs, —which are usually richer in metallic chirality tubes if all the CNTs are similarly synthesized—are desirable because such materials are more likely to be doped to become robust SCNTs than semiconducting chirality tubes. (The Fermi level of semiconducting tubes must move farther, because they must move outside of the single particle gap, semiconducting tubes have a higher normal state resistivity [3].) Particularly, the separation results in the formation of a material having 35 to 100 mole % of metallic chirality CNTs on one half of the suspension and another material having 65 to 100 mole % of non-metallic CNTs on the other half end of the suspension. More preferred, the material formed has about 50 to 100 mole % metallic chirality CNT, and most preferred having about 80 to 100 mole % metallic chirality CNTs, with corresponding non-metallic chirality CNT enrichments displaced on the other half side of the suspension. Because there is a strong correlation between superconductivity at higher temperatures and metallic chirality, the method can produce metallic chirality enriched and depleted concentrations of CNTs. Preferably, all tubes in the suspension should be prepared in a similar manner so that they have a similar defect concentration and therefore a similar doping profile. Such a commonality strengthens the correlation between superconductivity and metallic chirality.

### DESCRIPTION OF THE DRAWINGS

The invention can be better understood with reference to the following detailed description together with the appended illustrative drawings in which like elements are numbered the same:

FIG. 1 shows a preferred embodiment of a means of stabilizing the intimate proximity of tubes in a CSCNTL by using a bundling line.

FIGS. 2A & B illustrate two views of a preferred embodiment of the superconducting carbon nanotube electro-mechanical transducer; The basic elements consist of a low resistivity superconductor, an orphan SCNT (OSCNT), and some sort of harness to allow controlled displacement of the OSCNT relative to the low resistivity superconductor.

FIG. 3 illustrates a construction of a coherent superconducting carbon nanotube transmission line, where the constituent CSCNTLs and insulating tube(s) are composed of different material. Perhaps the insulating and conducting shells are both CNTs but with a different chirality. The resulting transmission line supports TEM waves.

FIG. 4 illustrates a preferred embodiment of a nanotube two-wire parallel line transmission line configuration that can support TEM waves; Similarly insulating materials will likely be required to provide electrical insulation between the two CSCNTLs;

FIG. 5 illustrates a preferred embodiment of a coaxial composite transmission line of this invention, whereby CNTs are preferably arranged with their axes parallel to a TEM transmission line and compose the inner and outer conductors of the transmission line (as with the case of FIG. 3, the CSCNTs are separated by an insulator);

FIG. 6 illustrates a preferred embodiment of a transmission lines of this invention, whereby CNTs are arranged to form each or any of the three conductors in a stripline transmission line; and

FIG. 7 illustrates a preferred embodiment of a transmission line of this invention, whereby the microstrip configuration is employed.

### DETAILED DESCRIPTION OF THE INVENTION

Inventor Zhao has found that phase coherent superconducting materials can be constructed by forming aggregates of proximate SCNTs having nanotubes in proximity, preferably maximal proximity, to each other in an aligned orientation [3] as set forth in co-pending application filed with express mail label number EV 328 519 010 US. Inventor Zhao has found that when a considerable portion of lengths of two or more nanotubes are aligned along an axis or curvilinear path and are maintained in proximity, preferably maximal proximity, materials with optimal superconducting properties can be maintained as set forth in co-pending application filed with express mail label number EV 328 519 010 US. The inventors have found that formed bundles into linear or curvilinear shapes, can be stabilized by a spiral winding or other similar stabilizing means that maintain the alignment and proximity of the nanotubes.

Moreover, it has been shown that by placing an individual OSCNT from a location where it is well-separated from superconductors to a location where the OSCNT is in intimate contact with a low resistivity superconductor (or a CSCNTL), that the resistivity of the OSCNT decreases [3]as set forth in co-pending application filed with express mail label number EV 328 519 010 US. Therefore as the distance separating the OSCNT from the low resistivity superconductor is changed, the resistivity of the OSCNT will undergo a marked change [3] as set forth in co-pending application filed with express mail label number EV 328 519 010 US. This change in resistivity can be used as: (1) a counter in the case of a sequence of impinging forces (mechanical, chemical, physical, e.g., pressure, electric, magnetic and/or electromagnetic forces); (2) a displacement sensor; (3) a strain gauge; (4) a deflection gauge; (5) a fatigue gauge; (6) a pressure gauge; (7) a temperature gauge (since the mechanical thermal fluctuations may be visible as electronic noise); (8) an accelerometer or (9) any other gauge, transducer, component of a gauge, or component of an electronic circuit.

The inventors have also found that a sensing device comprising two OSCNTs can be realized. Although one has less sensitivity if only one OSCNTs is monitored as compared with the case of one OSCNT and another CSCNTL (or a low resistivity superconductor), one has more sensitivity if one measures the proximity mediated changes in the system comprising the two OSCNTs. Therefore in applications where the net resistivity of two SCNTs is mediated by the proximity changes between these two CNTs, the ideal construction of this electro-mechnical transducer will comprise two OSCNTs. Similarly if the net diagmagnetism, critical current or any other superconducting parameter of the system of SCNTs is measured, this invention comprising two OSCNTs. will show a larger effect-or a greater sensistivity—due to the synergy between the two OSCNTs than the configuration comprising only one OSCNT and another CSCNTL. For the sake of concreteness, we claim for devices comprising two OSCNTs, that such devices more sensitively monitor changes in net resistivity (e.g., the resistivity of the parallel combination of both OSCNTs—as mediated by proximity—than in the configuration where the net or parallel resistivity is measured from a system comprising only one OSCNT and a CSCNTL which already had a resistivity much lower than the OSCNT. Apparatuses comprising least two OSCNTs to sense relative position or proximity can enable sufficient sensitivity in the measurement so that parameters other than resistivity can be monitored simultaneously in either OSCNT or in both OSCNTs. Such parameters include the critical current, diamagnetic response, gap size/shape, etc. Because there exists a synergy between the SCNTs, the net effect is greater than the sum of their individual effects. Therefore, the total diamagnetic response is larger than the sum of the diamagnetic responses when the tubes are well-separated from each other. Similarly the total conductance when the tubes are in parallel and intimately coupled will be greater than the sum of their individual conductances when the tubes are parallel and well-separated. Because two OSCNT are used, the effect of the synergy is more striking than were two CSCNTLs employed or one OSCNT and a CSCNTL employed.

Stabilizing Proximity

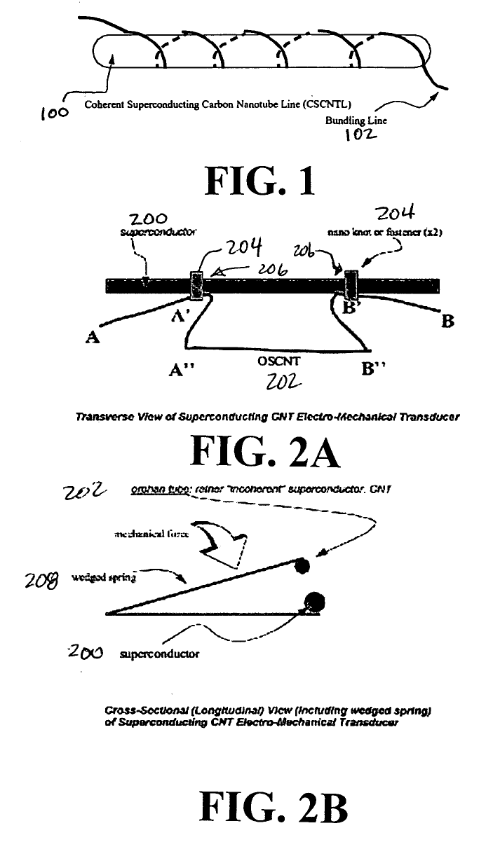

Because of the importance of proximity of nanotubes to achieve phase coherence [3] as set forth in co-pending application filed with express mail label number EV 328 519 010 US, preferred embodiments of the present invention are directed to methods for stabilizing proximity of nanotubes. By stabilizing mechanical proximity, one stabilizes the superconducting behavior, and lowers noise. The methods for stabilizing the nanotubes include wrapping, twisting, braiding, sheathing, gluing, encasing, knotting [10], Lorentz force adhering, tying or the like. FIG. 1 shows an example of one preferred method of stabilizing proximity in nanotubes using a bundling line, where a CSCNTL 100 is wrapped by a bundling line 102. Since current carrying lines can be made to attract each when current travels in the same direction in the lines, current mediated adhesion (i.e., Lorentz force) can be used to enhance the superconducting properties of SCNTs.

High Bandwidth Superconducting Mechanical/Electrical Transducer

A superconducting mechanical-electrical transducer can be constructed of nanotubes based on the principle of intertube coupling between proximate nanotubes. Reference [3] describes this as Josephson coupling for quasi-1D superconducting tubes. FIGS. 2A & B illustrate a preferred embodiment of a superconducting electromechanical transducer including a superconductor 200, an OSCNT 202 affixed to the superconductor 200 by fasteners 204 at two separated positions 206 along the superconductor 200 showing a and a wedged spring 208 formed by the OSCNT 202. Because the mass of the orphan tube is small, a large mechanical bandwidth is possible. The small mass also makes the device sensitive and makes loading to an incident energy small. Therefore, the transducers of this invention will be hard to detect electronically, acoustically or otherwise. Thus, the transducer of this invention is ideally suited for applications (e.g., biological), where minimal impact on its environment or on the system into which the transducer is placed is desired. Because the superconducting resistance (R) can be extremely small, the time constants (RC or R/L) will also be small so that the electronic bandwidth of these transducers will be large. Moreover, because nanotubes are durable, deformable and resilient, the tubes or tube bundles tend to recover their original configuration after bending or deformation [11] and, therefore, the transducers will be durable as well and less prone of fatigue.

The controlled displacement works as follows. A mechanical force causes the orphan tube and the associated low resistivity superconductor to come in close proximity thus changing the resistivity of the orphan superconducting carbon nanotube line between points “A” and “B.” Either the low resistivity superconductor or the orphan tube (i.e., OSCNTL) may consist of one or more SCNTLs. The displacement of the low resistivity superconductor or OSCNTL segment from A to A′ is constrained so that the allowed displacements in this segment do not cause an appreciable change in the resistance between points A and B. At point A′, the OSCNT is fixed next to the low resistivity superconductor. It is the movement of the segment A′-B′, and especially the segment A″ to B″, which then affects the resistance/impedance between A and B. As A″-B″ is brought in and out of proximity to the low resistivity superconducting line over the segment A′-B′, the resistivity between A and B is reduced and increased respectively. Two views of this transducer are provided in FIGS. 2A & B: a transverse view and a longitudinal view; Perhaps the most ideal embodiment of this involves both the OSCNT and the low-resistivity superconductor being composed of arm chair chirality SCNTs with the OSCNT being a SWNT and the low resistivity superconductor being a MWNT.

Similarly, locating an OSCNT in parallel and in proximity, preferably maximal proximity, to a cluster of tubes induces a greater degree of global phase coherence in the collection of superconducting tubes. The high bandwidth of the mechanical/electrical transducers of this invention is a function of the small mass of the section of the OSCNT that is moved from its mother bundle and the high mobility of electronic transport. These features enable sensitive conversion of mechanical motion or displacement into a corresponding electrical signal. The transducers of this invention are ideally suited in the following applications: a stress gauge, motion detector, trip wire, temperature sensor (thermal vibrations associated with a mechanically weakly coupled CNT is manifest in the electrical frequency spectra), modulator, demodulator, mechanical frequency counter, seismic sensor, etc. In this way the transducer converts mechanical position to an electrical signal.

Conversely, the transducers of this invention, when subjected to an electrical stimulus, generate mechanical motion/displacement in a controlled manner via the Lorentz Force. Consider two SCNTL. One line is insulated with a very thin sheath (so as to allow for Josephson coupling). This CSCNT insulated wire has current traveling in the opposite direction as the other SCNTL so that the Lorentz force causes the two SCNTLs to repel each other. In this way, the transducer of this invention converts an electrical signal to a mechanical displacement or force. The braiding, wrapping and/or tensioning of the tubes in the transducer mediates the mechanical-electrical interaction. Additionally, the orphan tube can be artificially weighted or stiffened to change the bandwidth or sensitivity of the transducer. FIGS. 2A & B depicts a preferred embodiment of a superconducting electro-mechanical transducer of this invention.

CNT Sorting Technology

Currently, no methods for the exclusive synthesis of either semiconducting or metallic chirality tubes exist, and this “lack of control, compounded by nanotubes' tendency to bundle together, has been seen as the primary block to nanotube-based electronic technology” [12]. Thus, the ability to quickly sort, separate or concentrate superconducting from nonsuperconducting CNTs represents an important step in the construction nanotube-based electronic apparatuses.

The inventors have found that the superconducting proximity effect forms a basis for sorting nanotubes based on their superconducting properties or characteristics. An OSCNTL has an electrical response that is very different when placed near an isolated semiconducting transport tube and away from superconducting materials, than when placed near a superconducting transport tube. Of course, one skilled in the art should recognize that a semiconducting chirality CNT may become a superconducting transport CNT with appropriate doping. Although a Raman technique is already known to uniquely identify the (n, m) indices of isolated CNTs [13], it is not necessary to know these indices if only knowledge of the presence of superconductivity of the CNT is desired. The sorting methods of this invention will likely be faster and less expensive than a technique that relies on Raman chirality identification.

A preferred method of sorting CNTs into SCNT and non-superconducting CNTs of this invention includes the steps of applying a magnetic force to a suspension of unsorted CNTs in an appropriate suspending agent. The procedure exploits the greater diamagnetic response of SCNTs relative to non-superconducting CNTs. SCNTs support a larger moment induced in them by the applied field as compared to non-superconducting CNTs. Once CNTs have their moments aligned via a magnetic field, an applied magnetic field gradient will produce a selective or a sorting force on the CNTs depending on the magnitude of the induced magnetic moments in the CNTs. This selective or sorting force causes the CNTs to differentially migrate resulting in a concentration gradient of CNTs in the suspension producing SCNTs rich and SCNT poor regions in the suspension. The format of this method can be similar to a PAGE type electrophoretic plate used in the biotechnology world, in a tube or in any other appropriate format.

Carbon Nanotube Transmission Lines

The compositions of this invention are ideally suited for the construction of high frequency electronic transport apparatuses having low electrical loss, low attenuation and low dispersion over a large frequency range. By forming the compositions into non-insulated or insulated superconducting electrical transmission elements, high frequency transmission lines with low attenuation and dispersion over a large frequency range are attainable. Such transmission lines can be macroscopic for traditional electrical power transmission or microscopic even down to the scale of the nanoscale tubes or nanotube bundles themselves depending on the particular application. When the CNT itself is an intrinsic electrical conductor, then the CNT itself can be used to create an electrical pathway between nanometer scale electronic components for use in IC chips, flexible circuits, or the like.

Macro-sized transmission lines can be formed using compositions of this invention made into composites including filaments or wires comprising proximate SCNTs, preferably maximally proximate SCNTs, where the filaments or wires will conduct electricity at high frequency with little or no loss at a temperature between about 20 K and 600 K, preferably, between about 125 K and 500 K, and particularly, between 250 K and 450 K. Because composite transmission lines are inherently inhomogeneous on a length scale equal to the length of the CNTs or the length and diameter of the CNTs, composite transmission lines will not likely transmit energy without significant loss for wavelengths that are comparable to or less than the length of the CNTs composing the transmission line conductor. The inhomogeneities arise from a tunneling resistance between tubes, which is much larger than the on-tube resistance. A percolative path mediated by strong intertube Josephson coupling is also likely to mitigate these inhomogeneities and mitigate the impedance mismatch. However, even for traveling wave having a wavelength much larger than the inhomogeneity scale, the attenuation will likely be non-negligible [14]. and mitigate the impedance mismatch. However, even for traveling wave having a wavelength much larger than the inhomogeneity length scale the attenuation will likely be non-negligible [14].

For frequencies above about 25 MHz, transmission lines are often used to control the signal's attenuation and dispersion. Many wireless applications involve high frequencies and could benefit from devices with high bandwidth, low power dissipation, low noise, low attenuation and low dispersion, i.e., from transmission lines comprising superconducting CNTs. Such arrangements of SCNTs can then support dissipation-free or nearly dissipation-free electronic transport.

The bandwidth of the SCNTs transmission lines of this invention are limited by the superconducting gap (i.e., fₘₐₓ≈2Δ/h), where h is Plank's constant. With Δ≈0.1 eV, fₘₐₓ≈0.5 10¹⁴ Hz or 50 THz. The one-dimensionality of the superconductivity of SCNTs also imposes some limitations on selecting optimal transmission line configurations. Since only TEM modes support a surface current that lies in one direction, one preferred type of transmission lines of this invention operate in TEM modes as opposed to TE or TM modes. The collocation of CSCNTLs also permits coherent transport in a direction transverse to the tube direction, another preferred embodiment of this invention. However, current induced in the traverse directions will likely support a lower power capability of the associated transmission line because the critical currents in the transverse direction are not expected to be as high as critical currents in the longitudinal (i.e., tube) direction. Since TE or TM modes generate surface currents that have a component that is not along the axial direction, we give attention to these non-TEM structures separately. Thus, the compositions of this invention can be used to construct TEM, TE and TM nanotube waveguides having a variety of configurations. These configurations include multiple non-nested CSCNTLs configurations and multi-walled concentric and non-concentric CSCNTL configurations. Preferably, the transmission lines of this invention are enclosed for hermetic or electromagnetic shielding etc.

TEM Configurations

CSCNTL as an Intrinsic Coaxial Transmission Line

One preferred embodiment of a nanoscale superconducting transmission line of this invention comprises a multiwalled carbon nanotube instrinsic superconducting coaxial transmission line (MWCNTISCTL) including two concentric CSCNTLs having different diameters and separated by an insulating annulus. The coaxial transmission lines involves at least two CSCNTLs: an outer CSCNTL and inner CSCNTL. The inner CSCNTL is nested inside the outer CSCNTL. Each CSCNTL includes at least one (one or a plurality of) superconducting SWCNT, where the plurality includes at least two adjacent or nearly adjacent nested tubes. Preferably, the two CSCNTLs are electrically insulated from each other by an insulator to prevent or reduce possible shorting. The insulator is interposed between the two conductors to provide electrical insulation between the two conductors and a medium through which the electromagnetic wave travels. The insulator can comprise an insulating coating on an outer surface of the inner CSCNTL or an insulating medium interposed between the outer surface of the inner CSCNTL and an inner surface of the outer CSCNTL. Such an insulating medium could be introduced between the CSCNTLs and allowed to diffuse the length of the tube by capillary action. Provided their electrical losses and dispersion are sufficiently low at the frequencies of interest, suitable insulating materials include fluorocarbons, hydrocarbons or the like having a viscosity low enough to support migration by capillary action.

Alternatively, the insulator can comprise one or plurality of interposed layers of semiconducting chirality CNTs. Preferably, the composite line includes an insulating coating on the outer surface of the outer CSCNTL to provide electrical insulation/isolation from the surrounding environment. This nanotube configuration can support TEM waves over the length of the MWCNTLISCLT.

One preferred embodiment of such a MWCNTISCTL construction comprises an inner electrode including a plurality of concentric adjacent layers (starting from a smallest radii CNT in the nesting), where each CNT is an optimal SCNT. A second plurality of concentric layers comprise an insulating layer comprising of CNT shells having semiconducting chiralities. This insulating layer constitutes the medium where the waves travel. A third plurality of concentric layers comprises the outer electrode comprising optimal nested SCNTs. Finally, a fourth plurality of concentric layers comprises an outer insulator, where the layers are electrically insulating and have semiconducting chiralities. The second plurality of concentric layers provides electrical insulation between the two conductors of the MWCNTISCTL and the fourth plurality provides electrical insulation between the outer conductor and the surrounding environment. The pluralities range between about 2 and about 15, preferably, between about 5 and about 15 and particularly, between about 8 and about 12.

To provide adequate isolation and noise suppression, the outer conductor preferably has a thickness of at least 2 to 3 penetration depths. This may require many shells in the MWNT. Inventor Zhao has estimated the penetration depth to be ˜200 nm [6] and as set forth in co-pending application filed with express mail label number EV 328 519 010 US. Thus, the construct radius is preferably between about 2 or 3 times the penetration depth representing a thicker construct than currently synthesized CNTs.

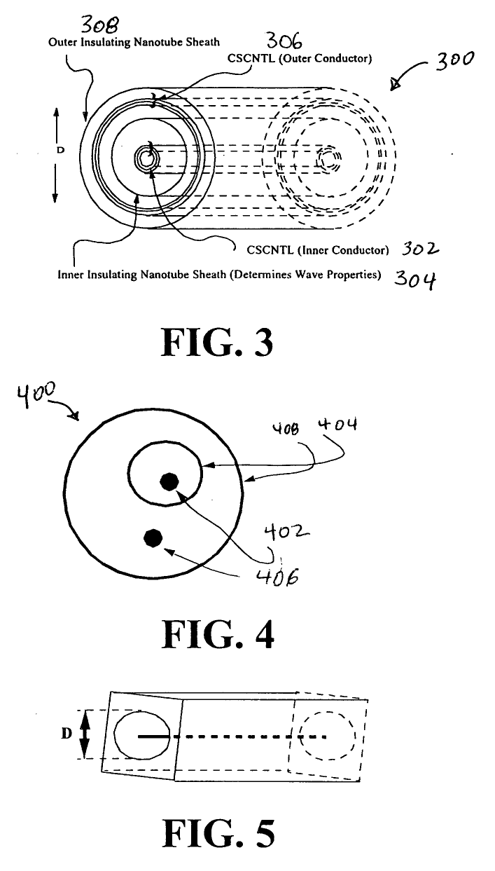

Another preferred construct of this invention is an intrinsic coax construct comprising of nanotubes which conduct in only one-dimension (the longitudinal direction). The construct is shown in FIG. 3, where the CSCNTL and insulating tubes are composed of different material. The construct 300 of FIG. 3 includes an inner CSCNTL 302, an inner insulator 304, an outer CSCNTL 306 and an outer insulator 308 and having a diameter D. Although only one insulating layer is shown to constitute the inner and outer insulators, the insulators can be multi-layered. Since the inner insulator determines some of the wave characteristics of the construct, the inner insulator may impose restrictions on the frequency of operation so that dispersion and attention limits are within bounds. This coaxial configuration yields only longitudinal surface currents, which is ideal for nanotubes.

Such constructs may be selectively grown to produce nested nanotubes of a specified chirality having specified diameters to some level of reproducibility [15]. Undesired tubes may be selectively burned or destroyed to produce a desired construct [12]. Alternatively, using the sorting process described above, appropriate nanotubes can be selected and manipulated by atomic force field microscopes so that smaller tubes can be inserted into larger tube to form desired MWNT. Next, a MWNT can be inserted into a larger nanotube until an coax transmission lines is made. The construction may be facilitated through the use of appropriate lubricants which an second as insulating materials between conductors or the lubricant can be highly volatile when used to construct multi-walls SCNTs so that the lubricant can be flashed out of the constructs, low molecular weight hydrocarbons being ideally suited for such lubricants.

Two Carbon Nanotubes Configurations as a Circular-Wire Parallel Pair Transmission Line

Another preferred embodiment of the a transmission line of this invention comprises a pair of parallel disposed conductors, where each conductor comprises two or more parallel nanotube lines. Each nanotube line may comprise one or a plurality of SCNT bundles, where each bundle has a small diameter combined together to make an effective CSCNTL having a larger diameter than its the constituent tubes. Such a construct would likely not significantly attenuate the signal. Alternatively, a single multi-walled nanotube with adjacent SCNT shells can suffice to compose a CSCNTL. Each conductor can comprise one SCNT or a plurality of proximate, preferably maximally proximate, SCNTs. This nanotube configuration can support TEM waves. In addition to the parallel configuration described above, a practical two-wire nanotube lines can be constructed as shown in FIG. 4. The construct 400 of FIG. 4 includes a first CSCNTL 402 surrounded by a first insulator 404 and a second CSCNTL 406 all being surrounded by a second insulator 408.

Composite Waveguide Composed of CSCNT's

A collection of nanoscale SCNTs forming a macroscopic conductors or transmission line will have two sources of impedance mismatch. The first source is the impedance mismatch between SCNTs aligned in different directions. Because the superconducting properties in a SCNT are not likely significantly anisotropic, this impedance mismatch may represent a relatively small and manageable problem. Preferably, the macroscopic conductors should possess good alignment among their constituent SCNTs. The second source of impedance mismatch is likely more serious. This impedance mismatch is the mismatch between the on-tube resistance and the intertube tunneling resistance. A large impedance mismatch means that the transmission line will loose signal power over a relatively short distance, an undesirable property. These sources of impedance mismatching may be reduced by thermal welding aligned SCNTs.

Alternatively, the construct preferably includes a percolative path of low resistivity comprising strong intertube Josephson coupling and extending over many SCNTs to mitigate impedance mismatch between the on-tube resistivity and the intertube tunneling resistivity as shown in FIG. 5. Because it is preferred that the surface currents propagate in the axial direction of the SCNTLs, a coaxial arrangement of SCNTLs is preferred supporting TEM modes. Provided that the wall of the composite material and the radius of the inner conductor is at least a few δ_{A}'s, the intrinsic wave impedance (i.e., η≡E/H) of the coax will be equal to that of the filling material (e.g., ˜377 Ω per square for free space). The intrinsic circuit impedance (i.e., Z_{c}≡V/I) of the coax will be equal to η/(2π)·ln(rₒᵤₜₑᵣ/rᵢₙₙₑᵣ). If rᵢₙₙₑᵣ<˜3 δ_{A} or the thickness of the outer conductor wall is <˜3 δA, this equality between η and Z_{c} will begin to breakdown.

Stripline (or Triplate Structure)

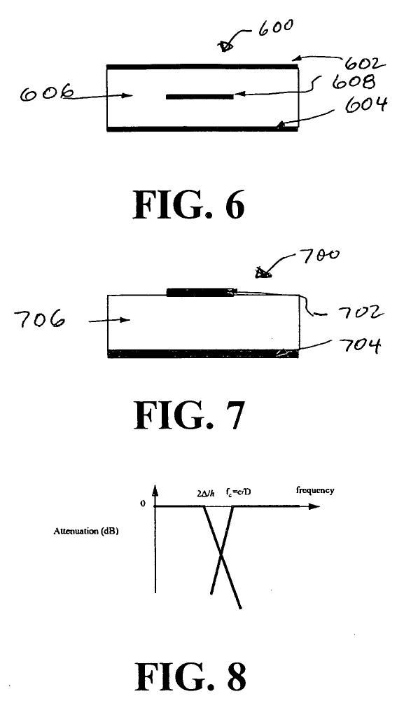

A stripline is a common transmission line construct and this invention also relates to striplines comprising CSCNTLs of this invention. The stripline topology supports TEM mode transmission. Preferably, the composite conductors in the stripline comprise aligned nanotubes. If the on-tube conductivity in a superconducting MWNT with many shells is not too anisotropic and highly conductive, the impedance mismatch between unaligned SCNTs will not be so significant. This allows the construction of SCNTL or conductors of this invention from randomly oriented SCNTs with acceptable losses. However, as discussed earlier, the impedance mismatch between the low on-tube resistance and the higher intertube tunneling resistance may give rise to large attenuations in composite transmission line structures. A stripline 600 of this invention is shown in FIG. 6 to include a top CSCNTL 602 and a bottom CSCNTL 604 and an interposed dielectric 606 including an embedded CSCNTL 608.

Microstrip

The most common superconducting transmission line configuration is the microstrip [17]. The microstrip topology supports quasi-TEM modes. By virtue of the asymmetry (no dielectric above the top strip), a TM mode is excited (in addition to the dominant TEM mode) [18,19]. The present invention also relates to microstrips comprising CSCNTLs of this invention. A microstrip 700 of this inventions is shown in FIG. 7 to include a top CSCNTL 702 and bottom CSCNTL 704 and an interposed dielectric 706.

Parallel Plate Transmission Line

Coplanar Waveguide, Slot-line and Coplanar strip (See ref. [19, p. 141). Parallel plate transmission lines can be constructed with CSCNTLs. The parallel plate topology supports quasi-TEM modes.

Non-TEM or Non-Quasi-TEM Configurations

As mentioned earlier, non-TEM transmission lines are also feasible due to the finite transverse gap in the single particle density of states. Because this gap is expected to be lower than the longitudinal gap, bandwidth and the power rating of non-TEM CSCNTLs are expected to be lower than that for TEM lines. Since single conductor waveguides are manifestly non-TEM [20], non-TEM transmission entails a single conductor transmission line. The rectangular waveguide is the most popular single-conductor transmission line.

Now we consider the possibility of a SCNT as an intrinsic single-conductor waveguide. The diameter of the tube will limit and determine the lowest frequency that the waveguide can support. This frequency is called the cutoff frequency (f_{c}) and is given by c/D where c is the speed of light and D is the inner diameter of the tube as shown in FIG. 5. Conversely, the superconducting gap determines the highest frequency that can support superconductivity, called the gap frequency (f_{g}) and its value is given by 2Δ/h where Δ is the superconducting gap (measured from the Fermi surface to either band edge) and h is Planck's constant. As illustrated in FIG. 8, in order to have a superconducting single-conductor waveguide, the cutoff frequency must be lower than the gap frequency. This requirement, c/D<2Δ/h, yields hc/(2Δ)<D or 12.4×10⁻⁷ eV-m/(2Δ)<D or 6.2×10⁻⁷ eV-m/Δ<D or 6.2×10² eV-nm/Δ<D. With Δ=0.1 eV [3], we obtain 6.20 μm<D. But this diameter is too big for current nanotube synthetic process, and even if one could make CNTs having such a large diameter, it is not clear that it would superconduct. Alternatively, if one considers the maximum diameter of a nanotube, the passband will then require frequencies which exceed the gap frequency and superconducting transport will not be possible.

Therefore the small diameter of the CNT would seem to preclude an intrinsic single conductor waveguide. But this leaves open the possibility of a composite SCNT single conductor waveguides for TE and TM modes. As before, we expect such waveguides to perform optimally when the axes of the CNTs are aligned or substantially aligned with that of the waveguide and when the tubes are continuous across the entire waveguide.

CSCNT Insulated Wire

Just as a MWNT can be made into an intrinsic co-axial transmission line, a MWNT can also be designed to serve as an insulated CSCNTL. As before, one preferred construct would comprise a plurality of layers starting from the smallest radii of suitably doped armchair chirality MWNTs. The plurality is a large plurality ranging between 10 and 20 or more MWNT layers. This plurality of MWNTs comprises a CSCNTL. The CSCNLT is then surrounded by a plurality of semiconducting chiralities CNTs, where the plurality is a smaller plurality ranging between about to and 10. The surrounding CNTS form the insulator for the CSCNTL.

CSCNT Coil Systems

CSCNT coils can be used to store energy, create a prescribed magnetic field or detect magnetic fields. Nested CSCNT coils can be used to make metal detectors with improved sensitivity.

Opposite-Moment Nested CSCNT Coils

Nested current carrying coils with their moments oppositely directed or nearly oppositely directed have a reduced net moment. However, the current carrying coils are in a meta-stable state and require mechanical support to prevent the moments from realigning. Having a reduced moment carries with it the desirable feature that magnetic forces between other moments will be relatively small which is advantageous for ergonomic and stability purposes.

CSCNT Relays

Low-loss relays can be produced from CSCNTLs of this invention. These relays form part of the current path in a perpetual-current coil system. These relays may in practice comprise a CSCNTL and a heater to heat the superconducting line above T_{c}. (A short segment of the CSCNTL may be doped to have a T_{c} that is not as large as the balance of the CSCNTL. Then the heater need only heat this short segment above its relatively low T_{c} in order to drive a segment of the current path normal.) Alternatively, instead of heat, a magnetic field or intense radiation, preferably, high frequency radiation, can be applied to the CSCNTL or portions thereof to quench the superconductivity.

Superconducting Fuse/Current Limiter

A segment of a CSCNTL may be doped to have a Tc that is not as large as the balance of the CSCNTL. Then total current is limited by this link, the weakest link.

Energy Storage System Involving Opposite-Moment Nested Coils and CSCNT Relays

Nested current carrying coils with their moments substantially oppositely directed can function as a battery or an energy storage system. Energy resident in the magnetic field can be extracted (e.g., via Lenz's Law) upon demand. If an effective room temperature relay is not used, then a cryogen-supported relay can be used in conjunction with CSCNT coils comprising the energy storage system.

Wound and Coated CNT Materials

Once enriched or suitably doped superconducting CNT materials are prepared as set forth in co-pending application filed with express mail label number EV 328 519 010 US, wound filament bundles, wires or the like or coated filaments, wires or the like can be prepared. Generally, these structures can be prepared by forcing a suspension, dispersion or other mixture of CNTs in a volatile solvent mixture through an orifice—regardless of orifice shape—with heating (to drive off the solvent) and winding of the extrudant with a retaining material to stabilize the proximity of the CNTs. Alternately, the material can be passed through a coating solution or the coating material can be co-extruded. In certain applications, it may be desirable for the coating material or the winding material to shrink when heat is applied so that a compressing force is applied to the extruded material. It should be recognized that for linear CNTs, the higher the sheer as the suspension moves through an orifice or the more size restricted the orifice, the more the resulting composite CNT will comprise aligned CNTs, which can then be stabilized.

In microelectronic applications, an enriched superconducting CNT material comprising CNTs having substantially the same superconducting properties can be sprayed through a nozzle, after being aligned in the tubing leading to the nozzle, into a patterned integrated circuit (IC) having patterned channels large enough to accommodate two or more CNTs side by side down the channels in proximity, preferably maximal proximity, forming superconducting electrical pathways between electronic components within the IC, where the CNTs are preferably MPSCNTs or MPSCNTLs. Chemical vapor deposition (CVD) can also be used to connect CNTs to a chip pad, so that the distance between the CNTs is small to lower the resistance of the connection. If the distance between the CVD connected SCNTs is small, then Josephson coupling between the tubes will also lowers the net resistance.

Suitable suspending agents for use in this invention include, without limitation, polyvinyl alcohol, polyvinyl acetates, cellulose ethers and finely divided inorganic powders in an appropriate solvent such as water, alcohols, a hydrocarbon (alkyl, alkenyl, or aryl), a chlorohydrocarbon (alkyl, alkenyl, or aryl), a chlorocarbon (alkyl, alkenyl, or aryl), a fluorohydrocarbon (alkyl, alkenyl, or aryl), a chlorofluorohydrocarbon (alkyl, alkenyl, or aryl), a chlorofluorocarbon (alkyl, alkenyl, or aryl), a fluorocarbon (alkyl, alkenyl, or aryl) or mixtures or combinations thereof.

### REFERENCES

The following references are have been cited in the specification above:

[1] G. M. Zhao, Y. S. Wang, “Possible superconductivity above 400 K in carbon-based multiwall nanotubes,” cond-mat/0111268 (i.e., website http-xxx-lanl-gov/PS_cache/cond-mat/pdf/0111/0111268.pdf).

[2] Guo-meng Zhao, “Transport and magnetic properties in multi-walled carbon nanotube ropes: Evidence for superconductivity above room temperature,” cond-mat/0208197 (i.e., website http-xxx-lanl-gov/PS_cache/cond-mat/pdf/0208/020,8197.pdf

[3] G. M. Zhao, “Quasi-one-dimensional superconductivity above 300 K and quantum phase slips in carbon nanotubes,” website http-xxx-lanl-gov/PS_cache/cond-mat/pdf/0208/020,8198.pdf;

[4] G. M. Zhao, “Raman spectroscopic evidence for superconductivity at 645 K in single-wall carbon nanotubes,” http://xxx.lanl.gov/PS_cache/cond-mat/pdf/0208/020,8200.pdf;

[5] Guo-meng Zhao, “Carbon nanotubes: Ballistic transport or room-temperature superconductivity?,” cond-mat/0208201 (i.e., website http-xxx-lanl-gov/PS_cache/cond-mat/pdf/0208/020,8201.pdf);

[6] Guo-meng Zhao, “Is Room Temperature Superconductivity in Carbon Nanotubes Too Wonderful to Believe?,” cond-mat/0307770 (website http-xxx-lanl-gov/PS_cache/cond-mat/pdf/0307/030,7770.pdf);

[7] R. Saito, M. Dresselhaus, G. Dresselhaus, Physical Properties of Carbon Nanotubes, (Imperial College Press, July 1998).

[8] M. Ouyang, J. -L. Huang, C. Cheung and C. Lieber, “Energy Gaps in ‘Metallic’ Single-Walled Carbon Nanotubes,” Science 292, 702 (2001) and references therein.

[9] P. Beeli, “Electrodynamics of a Superconducting (or Lossy Dielectric) Film on a Metallic Substrate,” J. Superconduct. 11, 775-784 (1998) and references therein.

[10] B. Vigolo, A. Penicaud, C. Coulon, C. Sauder, R. Pailler, C. Journet, P. Bernier, P. Poulini, “Macroscopic Fibers and Ribbons of Oriented Carbon Nanotubes,” Science 290, 1331 (2000).

[11] C. Dekker, “Carbon Nanotubes As Molecular Quantum Wires,” Physics Today 52(5), 22 (1999).

[12] P. Collins, M. Arnold and P. Avouris, “Engineering Carbon Nanotubes and Nanotubes Circuits Using Electrical Breakdown,” Science 292, 706 (2001).

[13] A. Jorio, R. Saito, J. Hafner, C. Lieber, M. Hunter, T. McClure, G. Dresselhaus, M. Dresselhaus, “Structural (n, m) determination of isolated single-wall carbon nanotubes by resonant Raman scattering,” Phys Rev Lett. 86, 1118-21 (2001).

[14] P. Beeli, “i^{th} Layer Electrodynamics: A Canonical Approach,” J. Appl. Phys. 86, 1514-1517 (1999).

[15] R. Schlittler, J. W. Seo, J. K. Gimzewski, C. Durkan, M. S. M. Saifullah, M. E. Welland, “Single Crystals of Single-Walled Carbon Nanotubes Formed by Self-Assembly,” Science 292, 1136 (2001).

[16] Magnusson, Transmission Lines and Wave Propagation, (Allyn and Bacon, Boston, 1965) sec. 9-2.

[17] T. Van Duzer and C. Turner, Principles of Superconductive Devices and Circuits, Second Edition (Prentice Hall, Upper Saddle River, N.J., 1999). p. 110.

[18] T. Edwards, Foundations for Microstrip Design, (Wiley, NY, 1992). Sec. 3.2.

[19] S. Ramo, J. Whinnery and T. Van Duzer, Fields and Waves in Communications Electronics, Third Edition (J. Wiley & Sons, New York, 1994). p. 414.

[20] Cheng, Field and Wave Electromagnetics, (Addison-Wesley, London, 1983). p.448.

All references cited herein are incorporated by reference. While this invention has been described fully and completely, it should be understood that, within the scope of the appended claims, the invention may be practiced otherwise than as specifically described. Although the invention has been disclosed with reference to its preferred embodiments, from reading this description those of skill in the art may appreciate changes and modification that may be made which do not depart from the scope and spirit of the invention as described above and claimed hereafter.

We claim:

1. A composition comprising a plurality of proximate superconducting carbon nanotube (SCNTS) and a means for stabilizing the SCNTs, where the means is adapted to stabilize proximity between the SCNTs.

2. The composition of claim 1, further comprising a plurality of SCNT bundles, where each bundle comprises a plurality of SCNTs.

3. The composition of claim 1, wherein the means stabilize electrical transport, impedance or Josephson coupling properties.

4. The composition for claim 1, wherein the means for stabilizing is selected from the group consisting of a stabilization structure, twisting the SCNTs, braiding the SCNTs, Lorentz force adhesion between the SCNTs and knotting of the SCNTs and mixtures or combinations thereof.

5. The composition of claim 4, where the stabilization structure comprises a sheath, an encapsulating matrix, an adhesion coating, a shrink wrap coating, internal filament wrap, an external filament wrap, or mixtures or combinations thereof.

6. The composition of claim 1, wherein the SCNTs are MWSCNTs.

7. A high bandwidth mechanical to electrical transducer comprising at least two nanotubes separated by a distance d, where modulating the separation d between the nanotubes produces or changes an electrical signal of the transducer or a multiwalled nanotube having an interwall separation d, where modulating the interwall separation d produces or changes an electrical signal of the transducer.

8. A transmission apparatus for transmitting electrical signals at non-zero frequencies comprising at least one coherent superconducting carbon nanotube line (CSCNTL), where the CSCNTL comprises plurality of superconducting carbon nanotube (SCNTs) and a means for stabilizing the SCNTs, where the means is adapted to maintain proximity between the SCNTs.

9. The apparatus of claim 8, wherein the signals comprise TEM signals or quasi-TEM signals.

10. The apparatus of claim 8, wherein the CNTs comprise an MWNT including an inner transmission line conductor and an outer transmission line conductor and an interleaving insulating CNT layer.

11. The apparatus of claim 8, further comprising an outer insulator.

12. The apparatus of claim 8, further comprising a plurality of CSCNTLs arranged in a parallel pair configuration.

13. The apparatus of claim 8, wherein the SCNTs are arranged with their axes parallel to the TEM transmission line and including an inner conductor and an outer conductor of the transmission line.

14. The apparatus of claim 8, wherein the apparatus is a stripline transmission line, a microstrip, a parallel plate, a coplanar waveguide, slot-line or a coplanar strip.

15. The apparatus of claim 8, wherein the SCNTs are MWSCNTs.

16. An energy storage device having improved energy storage properties comprising opposite-moment nested coils comprising coherent superconducting carbon nanotube line (CSCNTL) in a structure that mechanically holding the coils in place.

17. A low dissipation relay whose conduction path comprising a CSCNTL.

18. The above device or relay, wherein the coil or relay generate and store energy.

19. A method for sorting nanotubes in a bulk collection of nanotubes comprising the steps of:
suspending a bulk collection of nanotube in a suspending agent having sufficient viscosity to suspend the nanotube, while allowing movement of individual nanotubes through the suspension,
applying an external magnetic field across the suspension,
maintaining the field for a time sufficient for nanotube migration to occur to form a concentration gradient of nanotubes parallel to field lines, and
separating the nanotubes based on their superconducting properties.

20. A method for sorting nanotubes in a bulk collection of nanotubes comprising the steps of:
suspending a bulk collection of nanotube in a suspending agent having sufficient viscosity to suspend the nanotube, while allowing movement of individual nanotubes through the suspension, applying an external magnetic field across the suspension to align magnetic moments with the field, applying a magnetic field gradient across the suspension;
maintaining the fields for a time sufficient for nanotube migration to occur to form a concentration gradient of nanotubes parallel to field lines; and
separating the nanotubes based on their superconducting properties.

21. A method for stabilizing a nanotube structure comprising the step of:
applying a means for stabilizing to a composition comprising a plurality of proximate superconducting carbon nanotube (SCNTs).

22. The method of claim 21, wherein the composition comprises a plurality of SCNT bundles, where each bundle comprises a plurality of proximate SCNTs.

23. The method of claim 21, wherein the means stabilizes electrical transport, impedance or Josephson coupling properties of the composition.

24. The method for claim 21, wherein the means for stabilizing is selected from the group consisting of a stabilization structure, twisting the SCNTs, braiding the SCNTs, Lorentz force adhesion between the SCNTs and knotting of the SCNTs and mixtures or combinations thereof.

25. The method of claim 24, where the stabilization structure comprises a sheath, an encapsulating matrix, an adhesion coating, a shrink wrap coating, internal filament wrap, an external filament wrap, or mixtures or combinations thereof.
